(19) United States
(12) Patent Application Publication
(10) Pub. No.: US 2023/0185979 A1
(43) Pub. Date: Jun. 15, 2023

(54) System to Correlate Suitable Slurry Designs with Petrophysical While-Drilling Measurements in Real Time

(71) Applicant: Halliburton Energy Services, Inc., Houston, TX (US)

(72) Inventors: James Robert BENKLEY, Duncan, OK (US); Ronnie Glen MORGAN, Duncan, OK (US); Robert P. DARBE, Houston, TX (US); Paul J. JONES, Houston, TX (US); John Paul Bir SINGH, Houston, TX (US)

(21) Appl. No.: 17/550,064

(22) Filed: Dec. 14, 2021

(51) Int. Cl. G06F 30/13; E21B 41/00; E21B 33/14

(52) U.S. Cl. CPC G06F 30/13; E21B 41/00; E21B 33/14

(57) ABSTRACT

A method of designing a cement blend for a wellbore isolation barrier from datasets indicative of drilling a wellbore. The drilling datasets may include drilling equipment data, bottom hole assembly data, and mud system data. A drilling path record comprising depth segments with averaged data values of drilling data can be generated by processing the drilling datasets. A design process can determine a stress state for each depth segment of the drilling path record and design a cement blend with mechanical properties exceeding the stress state. The design process can determine an optimized cement design comprising the cement blend for each depth segment of the drilling path record.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

In oil and gas wells a primary purpose of a barrier composition such as cement or a sealant is to isolate the formation fluids between zones, also referred to as zonal isolation and zonal isolation barriers. Cement is also used to support the metal casing lining the well, and the cement provides a barrier to prevent the fluids from damaging the casing and to prevent fluid migration along the casing.

Typically an oil well is drilled to a target depth with a drill bit and mud fluid system. A metal pipe (e.g., casing, liner, etc.) is lowered into the drilled well to prevent collapse of the drilled formation. Cement is placed between the casing and formation with a primary cementing operation.

A primary cementing operation pumps a cement blend tailored for the environmental conditions of the wellbore. The primary cementing operation may utilize specialized pumping equipment on the drilling rig or transported to the drilling rig. The primary cementing operation may utilize various specialized downhole equipment such as wipers, darts, float shoes, and casing centralizers. The cement is typically pumped down the casing and back up into the annular space between the casing and formation.

The well drilling operation may be interrupted before the target depth due to wellbore conditions encountered in the subterranean formation. The premature end to the drilling operation may cause the production company to request changes to the design of the cement blend for the primary cementing operation. A method of designing a cement blend for a primary cementing operation based on the current drilling operation is desirable.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a cut-away illustration of an embodiment of a well system.

FIG. 2 is a block diagram of a communication system according to an embodiment of the disclosure.

FIG. 3A is a logical flow diagram depicting a method of generating a drilling path record according to an embodiment of the disclosure.

FIG. 3B is an illustration of the method of generating a drilling path record according to an embodiment of the disclosure.

FIG. 3C is an illustration of the storage of the drilling path record according to an embodiment of the disclosure.

FIG. 4A is a logical flow diagram depicting a method to generate a cement design record according to an embodiment of the disclosure.

FIG. 4B is an illustration of the method to generate a cement design record according to an embodiment of the disclosure.

FIGS. 4C and 4D is a logical flow diagram depicting a method of a design process to generate a cement design record according to an embodiment of the disclosure.

FIG. 5A is a logical flow diagram depicting a method to generate a cement design record using real-time drilling data according to an embodiment of the disclosure.

FIG. 5B is an illustration of the method to generate a cement design record using real-time data according to an embodiment of the disclosure.

FIG. 6 is a cut-away illustration of a primary cementing operation according to an embodiment of the disclosure.

FIG. 7 is a block diagram of a computer system suitable for implementing one or more embodiments of the disclosure.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

An oil well can be drilled with a drill bit and mud system. A suitable drilling rig can be located on a drilling pad or offshore above the drilling location. As the drill bit penetrates the earth strata, a drilling mud is pumped down a drill string to bring cuttings back to surface. The drilling mud can be water based or oil based with a clay material to increase the weight of the fluid. The drilling mud may also contain various other chemicals to for compatibility with the wellbore and to enhance the ability to return cuttings to surface. The weight of the drilling fluids can retain the desired hydrocarbons in the formation until the well is completed. A string of casing, generally defined as individual lengths of pipe threaded together, can be lowered into the drilled wellbore to prevent the wellbore from caving in or collapsing.

During well completion, it is common to introduce a cement slurry, e.g., cement composition, into the annulus formed between the casing and the wellbore. The cement typically used for cementing oil wells can be a Portland cement comprised of a hydraulic cement with a source of free lime and alkali ions, a source of calcium carbonate, a source of calcium sulfate and an organic component. The composition of the cement can be tailored for compatibility with the properties of a subterranean formation or production zone. The cement slurry may also include various additives to modify the hydraulic cement for a given pumping operation. The additives may modify the viscosity of the cement slurry for the pumping operation. One or more additives may control the set time, e.g., accelerate or retard. For example, the cement slurry for an extended wellbore with a high bottom hole temperature may have chemicals added to decrease the pumping pressure, e.g., viscosity modifier, and to retard the set time for the temperature.

A primary cementing operation can include various downhole equipment that can enhance the quality of the cement bond. A float shoe can be coupled to the end of the casing string, also referred to as casing. The float shoe can include one or more flow control devices such as check valves. A stage tool, a casing valve operated by various positioning tools, can be included on the casing string to decrease the pumping pressure values for extended reach wells, e.g., long casing strings. A plurality of casing centralizers can maintain the annular gap between the casing and the wellbore. The cement slurry can be separated from the drilling fluids and various other fluids used in the pumping operations by a combination of downhole tools and specialized fluids, e.g., spacer fluid, by pump down cementing plugs, wiper darts, wiper balls, foam balls, and various other pump down articles. The type of downhole equipment selected can depend on the well type, formation properties, drilling mud properties, wellbore environment, e.g., pressure and temperature, or a combination of factors.

The cement pumping operation can include one or more pumping units. The pumping units can include one or two mixing drums with capacity pumps. The mixing system can include data acquisition system with pressure and density sensors. The cement pumping system can be trailer mounted or skid mounted.

The cement sheath placed in the annulus between the casing and the wellbore can be evaluated with an acoustic logging tool conveyed into the casing by wireline after the primary cementing pumping operation has been completed and the cement has hardened. An acoustic logging can evaluate the cement sheath for quality and consistency.

A primary cementing job may provide an isolation barrier to isolate the formation to prevent formation fluids from migrating and damaging the casing. An analysis of the wellbore from drilling data may determine a wellbore stress level also referred to as a wellbore stress state. The cement blend and pumping procedure can be designed to withstand the wellbore stress state. A cement blend and pumping procedure may be designed based on the planned drilling trajectory and anticipated wellbore environment. However, the drilling process can prematurely end due to wellbore irregularities or drilling equipment issues. The drilling operation can end before the well reaches a target depth. The wellbore path may deviate from the planned drilling trajectory. The cement blend and pumping procedure may need to be redesigned due to the change to the planned drilling trajectory or wellbore environment. This redesign or revision to the cement design may cause unwanted and costly delay. A method of designing a cement blend and pumping procedure based on real-time data is desirable.

One solution to the unplanned changes in a drilling operation is developing a design process that determines an average value of drilling data based on depth segments. The design process can divide a wellbore length into depth segments and separate the drilling dataset into each depth segment. The design process can then determine an average value of the drilling data for each depth segment. The stress level of the isolation barrier can be determined for each depth segment. The design process can design a cement blend with mechanical properties exceeding the stress level. The design process can continually evaluate the design of the cement blend and stress state of the isolation barrier of the wellbore as the drilling operation progresses. The cement blend can be verified with laboratory testing when the drilling operation stops. The design process can determine an optimized cement design comprising a cement blend for each depth segment, a pumping procedure, and a bill of materials for downhole equipment.

Disclosed herein is a method of designing an optimized cement design based on drilling datasets. A design process can determine a cement blend based on an isolation barrier stress state. The optimized cement design can be updated with real-time drilling datasets.

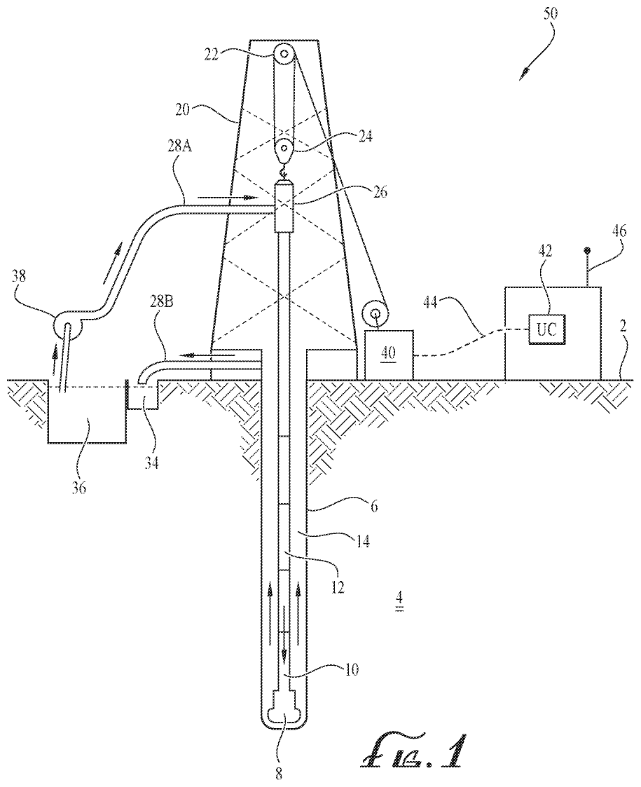

Turning now to FIG. 1, illustrated is a wellbore drilling environment 50 that can be utilized to monitor the drilling of a wellbore. In some embodiments, the wellbore 6 can be drilled into the subterranean formation 4 using any suitable drilling technique and can extend in a substantially vertical direction away from the earth's surface 2. At some point in the wellbore 6, the vertical wellbore portion can transition into a substantially horizontal wellbore portion. The drilling system can include a drill bit 8 and a bottom hole assembly 10 mechanically coupled to a tubular commonly referred to as drill pipe 12. The drill pipe 12 generally comprises an inner bore for the transfer of drilling fluids to the drill bit 8. The drilling fluids, e.g., drilling mud, can cool and lubricate the drill bit 8 and lift drill cuttings to the surface along the annulus 14 between the drill pipe 12 and wellbore 6. In some contexts, the drill pipe 12 can be referred to as a drill string 12.

The drilling system can comprise a drilling rig 20 including a lifting mechanism, a fluid system, and a rotation mechanism. The lifting mechanism can be described as a block and tackle system including a crown block 22 and a traveling block 24 releasably connected to the drill string 12. The crown block 22 stays stationary while the traveling block 24 raises and lowers the drill string 12 and downhole assembly, e.g., drill bit. A draw-works 40 can provide the mechanical force, via a drill line, to raise and lower the traveling block 24. The lifting mechanism can control the amount of weight applied to the bottom hole assembly (BHA) 10 and drill bit 8. The lifting mechanism may include a plurality of sensors such as block height sensor, block speed sensor, hook load sensor, and weight indicator.

The drilling system can comprise a fluid system to transport drill cuttings to surface. The fluid system can provide the drilling fluid flowrate and pressure down the inner bore of the drill string 12 to the drill bit 8. The fluid system can comprise a return line 28B, a shale shaker 34, a mud tank 36, a suction line, a mud pump 38, a stand pipe 28A, and a swivel 26. The fluid system provides a fluid circuit to transport drill cuttings to surface, separate the cuttings, and circulate clean drilling mud back to the drill bit 8. The mud tank 36 provides the mud pump 38 a volume of drilling fluid to circulate down the drill string 12 via the stand pipe 28A and swivel 26. The drilling fluid, e.g., drilling mud, cools and lubricates the drill bit 8 while transporting the drill cuttings back to surface via the annulus 14. The shale shaker 34 receives the drilling fluid, via the return line 28B, separates the drill cuttings from the drilling mud, and returns the drilling mud to the mud tank 36 to cool. The fluid system may include a wellhead, blowout preventer, and bell nipple for pressure control of the wellbore environment. The fluid system may include a plurality of sensors such as flowrate sensors, pressure sensors, and tank volume sensors.

The drilling rig 20 can comprise a rotation mechanism for rotating the drill string 12. The rotation mechanism can provide the rotational speed of the drill bit 8 and drill string 12. The rotational mechanism for the drilling rig 20 can include a kelly 32, a kelly bushing, and a rotary table. The rotary table can mechanically couple the kelly 32 with the kelly bushing to the rig structure to provide rotation to the drill string 12. The rotation of the rotary table provides rotation to the drill string 12 via the kelly 32. In a context, the rotational motion mechanism of the drilling rig 20 can include a top drive device to provide mechanical rotation of the drill string 12. The rotation mechanism can include sensors such as torque sensor and rotary speed sensor.

The drilling rig 20 can include a BHA 10 mechanically connected to the drill string 12. The BHA 10 can include a rotary steerable assembly to control the direction of drilling such as an Measurements-While-Drilling (MWD) and/or Logging-While-Drilling (LWD) assembly. The BHA 10 can communicate via the fluid system through mud-pulse technology. The rotary steerable assembly can measure wellbore properties, drilling parameters, and direction measurements with various sensors.

The wellbore drilling environment 50 may include surface equipment for the control and monitoring of the drilling process. The drilling system can include a unit controller 42 comprising a processor, a non-transitory memory, and a communication device 46. The unit controller 42 can be communicatively connected to the drilling system via wired cable 44 or a wireless communication method, e.g., WIFI. The unit controller 42 can direct the drilling via drilling personnel, e.g., the driller, or may automate a portion of the drilling process via wired or wireless communication. A plurality of sensors for the lifting mechanism, the fluid system, the rotation mechanism, and the wellhead can provide feedback to the unit controller 42 via a data acquisition (DAQ) unit. The communication device 46 can communicatively connect the unit controller 42 to one or more remote user devices as will be disclosed herein after.

The data gathered by the sensors can include stress, strain, flow rate, pressure, temperature, and acoustic data. The fluid sensors can include a communication method for the BHA 10. The unit controller 42 can communicate with the BHA 10 via the fluid system. The BHA 10 can transmit datasets of directional data, wellbore environment, and drilling parameters to the unit controller 42 via the fluid system.

Although the wellbore drilling environment 50 is illustrated as a wellsite on land, it is understood that the wellbore drilling environment 50 can be offshore. The wellhead can be mechanically coupled to surface casing to anchor the wellhead and blowout preventer at surface 2. The wellhead can include any type of pressure containment equipment connected to the top of a casing string, such as a surface tree, production tree, subsea tree, lubricator connector, blowout preventer, or combination thereof. The wellhead can be located on a production platform, a subsea location, a floating platform, or other structure that supports operations in the wellbore 6. In some cases, such as in an off-shore location, the wellhead may be located on the sea floor while the drilling rig 20 can be located on a structure supported by piers extending downwards to a seabed or supported by columns sitting on hulls and/or pontoons that are ballasted below the water surface, which can be referred to as a semi-submersible platform or floating rig.

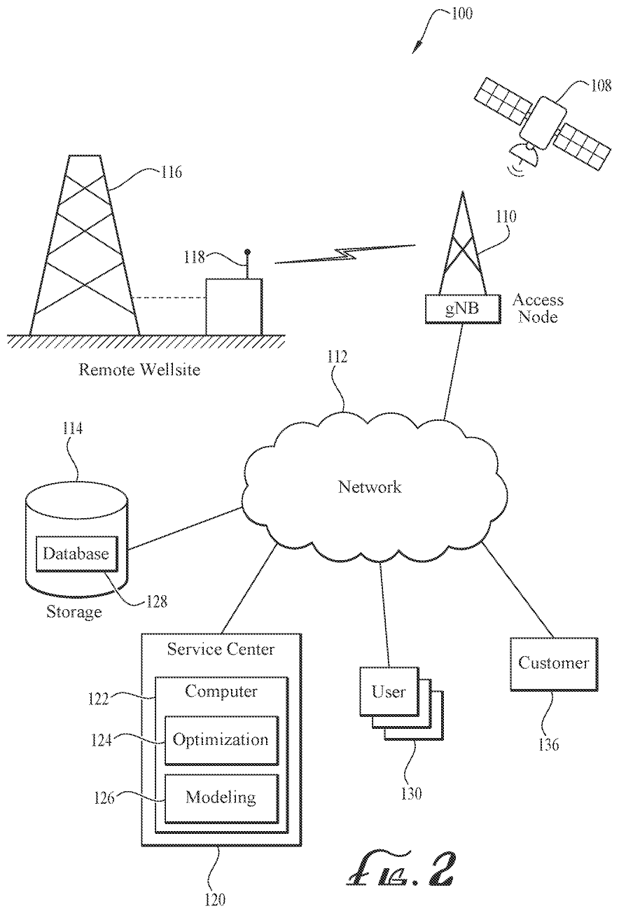

Turning now to FIG. 2, a communication system 100 is described. The communication system 100 comprises a remote wellsite 116, a cellular site 110, a network 112, a storage computer 114, a computer system 122, a plurality of user devices 130, and a customer device 136. A remote wellsite 116 with a communication device 118 (e.g., communication device 46 of FIG. 1) can transmit via any suitable communication means (wired or wireless), for example wirelessly connect to a cellular site 110 to transmit data to a storage computer 114. The cellular site 110 can be communicatively connected to a network 112 that can include a 5G network, one or more public networks, one or more private networks, or a combination thereof. A portion of the internet can be included in the network 112. The storage computer 114 can be communicatively connected to the network 112. The service center 120 can have one or more servers and/or computer systems 122. A cement optimization process 124 can be executing on a computer system 122 in the service center 120.

A communication device 118 on a remote wellsite 116 can transmit data collected from the equipment sensors, wellhead sensors, and/or BHA 10 to the storage computer 114. The communication device 118 can comprise a storage device and a data transmission device. The communication device 118 can wirelessly connect to the cellular site 110 continuously or at a predetermined schedule. In some embodiments, the communication device 118 can connect or attempt connection to the storage computer 114 via the cellular site 110 based on an established schedule. In some embodiments, the cement optimization process 124 can request the data from the communication device 118 based on an established schedule. The storage computer 114 can connect or attempt connection to the communication device 118 via cellular site 110 based on an established schedule. The communication device 118 can wirelessly connect to the network 112 via satellite communication 108.

The storage computer 114 can include a historical database 128 of datasets from remote drilling operations. A remote wellsite 116 can transmit one or more datasets indicative of a drilling operation. For example, the historical database 128 may comprise a plurality of datasets from wellbore drilling operations at remote wellsites, e.g., 116. The plurality of datasets within the historical database 128 may comprise one or more remote wellsites within the same field as will be described further herein.

A user device 130 can transfer a drilling dataset from the storage computer 114 to a cement optimization process 124 executing on a computer system 122 in the service center 120. The drilling dataset can include the drilling system data and fluid system data collected from remote wellsite 116 over a designated time period. The drilling dataset can include multiple types of datasets from a complete drilling operation. Alternatively, a drilling dataset from the storage computer 114 can be transferred automatically or via a scheduler to a cement optimization process 124. The cement optimization process 124 can process the drilling dataset indicative to the drilling operation of the remote wellsite 116. The user device 130 can receive customer inputs from a customer device 136. The user device 130 can transmit the customer inputs and at least one dataset from the historical database 128 to the analysis process via the cement optimization process 124. The cement optimization process 124 may access one or more models 126 during a design process and can recommend a cement blend or changes to a design cement blend from analysis of the drilling dataset.

A remote wellsite 116 may transmit a periodic dataset indicative of a current drilling operation to the cement optimization process 124. The cement optimization process 124 may recommend changes to the design cement blend based on one or more periodic datasets received from the remote wellsite 116 via the communication device 118.

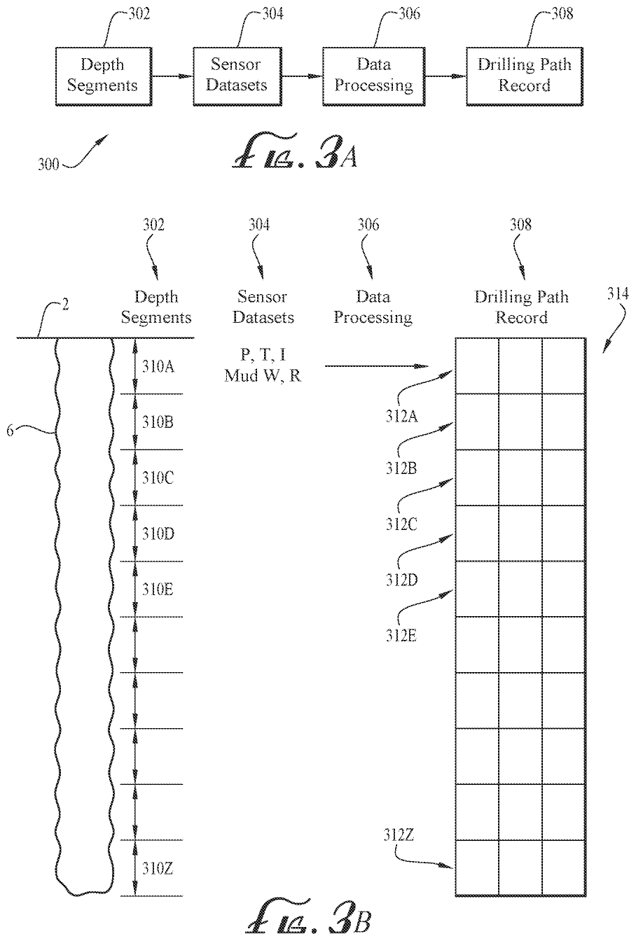

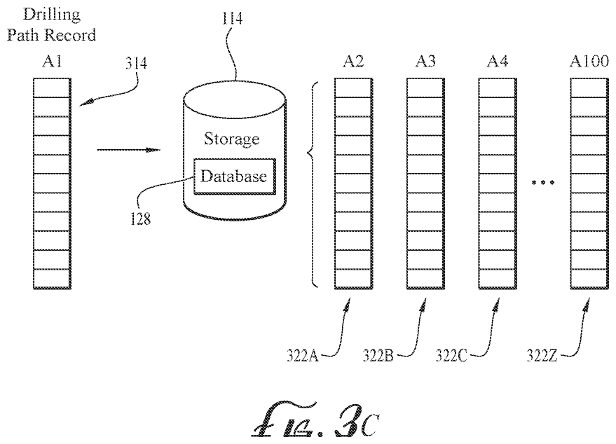

The drilling operation of FIG. 1 may transmit drilling datasets via the communication system 100 of FIG. 2 to storage computer 114. The drilling datasets may include data indicative of the drilling operation including the drilling equipment and the BHA 10. A process executing on a computer system, e.g., computer system 122, can generate a drilling path record from the drilling datasets. Turning now to FIG. 3A and FIG. 3B, a method 300 for generating a drilling path record according to some embodiments of the disclosure. A data process executing on the computer system 122 can retrieve a drilling dataset from storage computer 114. Alternatively, the drilling dataset can be transmitted to the computer system 122. At step 302, a data process can divide the drilling dataset into depth segments 310 as illustrated in FIG. 3B. A depth segment 310 can include a linear distance measured along the axis of the wellbore 6. For example, a depth segment 310 can be one foot of the total length of the well. The depth segment 310 can be equal in size from the surface 2 to the bottom, e.g., the end, of the wellbore 6. A wellbore 6 that measures 10,000 ft can include 10,000 separate depth segments 310 of one foot length. The depth segments 310 can be sequentially placed. For example, depth segment 310A begins at the surface 2 and extends towards the bottom of the wellbore 6 for a predetermined length, e.g., one foot. Depth segment 310B begins at the end of depth segment 310A and extends towards the bottom of the wellbore 6. Each subsequent depth segment 310, for example 310A through 310Z, begin at the end of the previous depth segment 310. In an alternative embodiment, the depth segment 310 can vary in length. For example, the depth segments 310 near the surface 2, for example 310A, 310B, and 310C may be ten foot in length and the depth segments 310 at the bottom of the wellbore 6, for example depth segment 310Z in a formation of interest, may be one foot in length.

At step 304, the data process can divide the measurement data within the drilling dataset into the corresponding depth segments 310A-Z. The drilling dataset comprises drilling equipment datasets, datasets from BHA 10, and mud system datasets. The drilling equipment datasets can include periodic datasets of pressure, flowrate, torque, hook load and rpm. The dataset from the BHA 10 can include periodic datasets from an MWD and/or LWD drilling system comprising temperature, pressure, fracture gradient, pore pressure, loss data, lithology, formation porosity, formation permeability, and trajectory. The mud system dataset can include a mud report and periodic datasets of circulation pressure, density, and mud rheology.

At step 306, the data process can process the datasets to determine a value representative of the depth segment 310A-Z. The dataset from the BHA 10 can include raw data, e.g., mud-pulse data, processed data, or combinations thereof. The raw data comprises measurements by gamma ray, neutron density, resistivity, or combinations thereof in the form of mud-pulse signals. The data process can transform the mud-pulse data into processed datasets with measurement values, e.g., temperature or pressure. The processed datasets from the BHA 10 can comprise the wellbore measurements and/or formation data values in the form of formation lithology, pore pressure, or combinations thereof. The processed datasets from the BHA 10 can comprise periodic datasets, for example wellbore trajectory. The data process can determine a segmented set of periodic datasets, a segmented set of measured values, or combinations thereof for each depth segment. In some embodiments, the data process may produce a post-processing periodic dataset for each segmented set of the periodic datasets by applying one or more data reduction techniques to smooth the periodic set of data. The data reduction techniques may include data pre-processing, data cleansing, numerosity reduction, or a combination thereof. The data pre-processing technique may remove out-of-range values and flag missing values within the dataset. The data cleaning process may include the use of statistical methods, data duplicate elimination, and the parsing of data for the removal of corrupt or inaccurate data points. The post-processing periodic dataset may be saved to drilling path file within the computer system 122 or storage computer 114.

In some embodiments, the post-processing periodic dataset may be averaged to produce an averaged value representative for each set of periodic data. The average value may be a single value that represents a plurality of values across a given duration, e.g., depth segment 310. The average value may be determined by applying one or more mathematical techniques such as an arithmetic mean, a median, a geometric median, a mode, a geometric mean, a harmonic mean, a generalized mean, a moving average, or combination thereof. The data process may assign the segmented set of processed data values comprising the averaged value, the set of measurement values, or combinations thereof to a corresponding depth segment to the drilling path file. In some embodiments, the average value may be determined as each of the plurality of periodic datasets is generated, for example, in real-time or, alternatively, at a later time. The data process can generate a processed dataset comprising measurement values and averaged values.

Although step 302, step 304, and step 306 are presented in sequence, it is understood that the steps may occur in a different order, concurrently, or a combination thereof. For example, the data process may process raw mud-pulse data to convert the raw data into periodic datasets, a set of measurement values, or combinations thereof prior to step 302. In another scenario, the data process may receive or retrieve periodic datasets and measurement values converted from raw mud pulse-data. It is understood that the data process may return to one or more steps to compete the data processing before stepping to step 308.

At step 308, the data process can generate a drilling path record 314 comprising the processed dataset, e.g., average values, of the measured data corresponding the depth segments 310A-Z. A data segment 312 comprises the processed dataset, e.g., averaged data values, for a depth segment 310. For example, the data segment 312A can correspond to depth segment 310A. The data segment 312 can comprise the well trajectory (e.g., inclination), wellbore environment conditions (e.g., temperature and/or pressure, drilling parameters (e.g., torque, weight on bit, RPM), formation data (e.g., lithology), and mud data (e.g., mud weights, rheology).

Turning now to FIG. 3C, the storage of the drilling path records is illustrated. In some embodiments, the data process can save the drilling path record 314 to a historical database 128 in a storage computer 114 as shown in FIG. 2. The historical database 128 can comprise drilling path record 322 from other drilling operations. For example, the historical database 128 may include drilling path record 322A through drilling path record 322Z for previous drilling operations. Although the historical database 128 is shown in the storage computer 114, it is understood that the historical database 128 may be located on a computer system, e.g., computer system 122, in the service center 120. In an alternate embodiment, the historical database 128 may be located on a virtual computer system in a communication network, e.g., a 5G network.

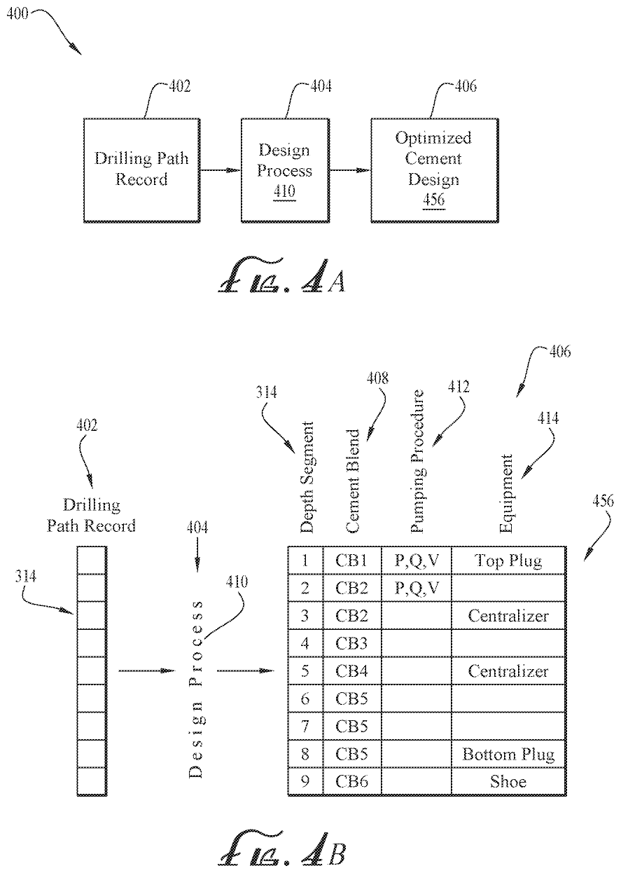

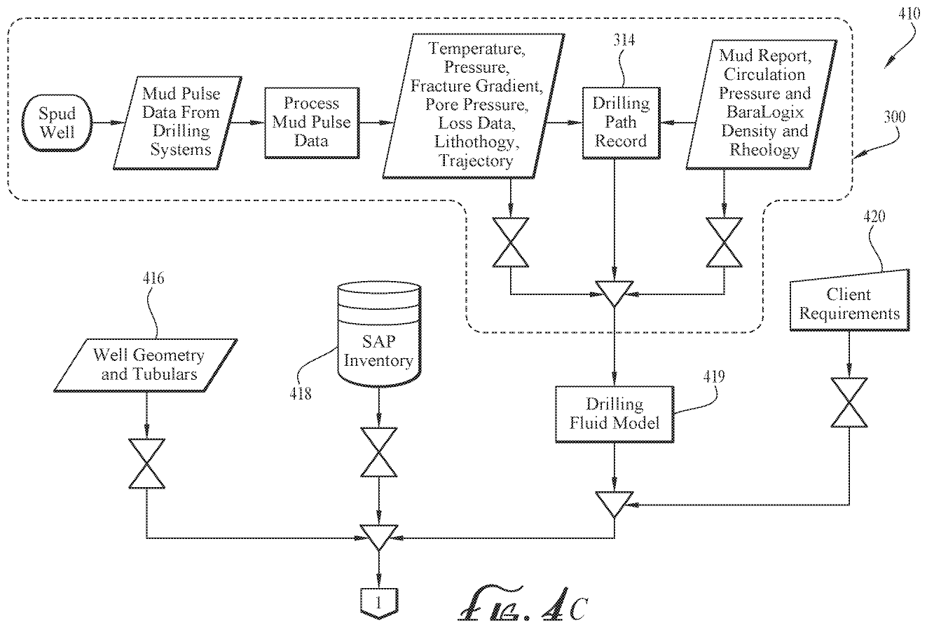

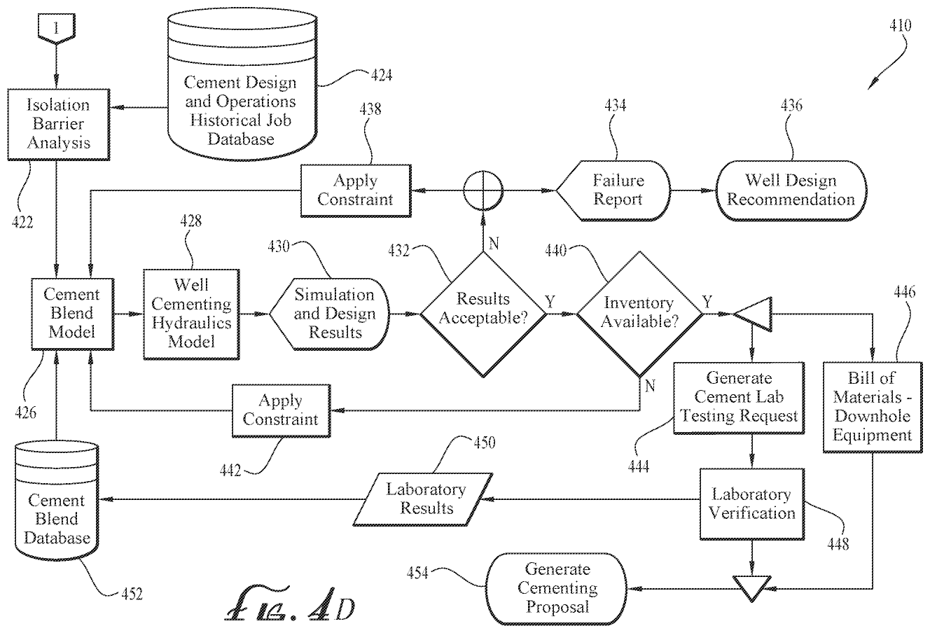

Turning now to FIG. 4A, a logical flow diagram depicting a method to generate a cement design record is disclosed. In some embodiments, a method 400 of generating an optimized cement design can comprise a design process. At step 402, a drilling path record 314 can be retrieved from a historical database 128, a computer system 122, a virtual computer or combinations thereof.

At step 404, a design process 410 can utilize the drilling path record 314 as an input. The design process 410 can include an inventory of well tubulars, material availability, client requirements, laboratory testing, or combinations thereof. The design process may be the process 124 on the computer system 122 of FIG. 2. The design process 410 may access one or more models 126 and generate an optimized cement design 456 as will be described herein.

At step 406, as illustrated in FIG. 4B, the design process 410 can output an optimized cement design 456 comprising a cement blend 408, a pumping procedure 412, a downhole equipment 414, or combinations thereof for a set of depth segments. The cement blend 408, the pumping procedure 412, the downhole equipment 414, or combination thereof can correspond to a depth segment 310. For example, cement blend 408A, pumping procedure 412A, and downhole equipment 414A can correspond to depth segment 310A. The cement blend 408 and pumping procedure 412 can change from one depth segment 310 to the next. For example, the cement blend 408F-G may be same in depth segment 310F-G and change to a different blend, cement blend 408H, in depth segment 310H. The pumping procedure 412 may change from the depth segment 310A at the surface to the depth segment 310F at a middle depth. The pumping procedure 412 comprises pump pressures, pump flowrates, pump volumes, various additives, or combinations thereof. For example, the pumping procedure 412Z may include higher pressure values than the pump procedure 410A. The downhole equipment 414 may correspond to a depth segment 310. For example, optimized cement design 456 may include a downhole equipment 414E, e.g., a centralizer, at depth segment 310E.

Although the design process 410 is described as outputting an optimized cement design 456, the design process 410 may include a secondary objective comprising a design objective, an operational objective, a cost objective, an inventory objective, or combinations thereof. The secondary objective may be an input, e.g., customer input, or a design constraint as will be described herein. The secondary objective can direct the design process 410 to output an optimized cement design 456 comprising one or more desired feature. For example, the secondary objective may direct the design process 410 to produce a polymer-based cement blend 408 and/or prevent the design process 410 from producing a Portland cement-based cement blend 408.

Turning now to FIGS. 4C and 4D, a logical flow diagram can describe the design process 410 to generate an optimized cement design 456. In some embodiments, the design process can retrieve a well geometry and tubulars 416, an inventory of cement and equipment 418, the drilling path record 314, and a set of client requirements 420. The well geometry and tubulars 416 comprise the wellbore tubulars and installation procedure provided by the customer, a wellbore construction model, or combinations thereof. The wellbore tubulars can include surface casing, primary casing, secondary casing, liners, and production tubulars. The inventory of cement and equipment 418 can identify the material availability for the optimized cement design 456. The set of client requirements may include a material requirement, a construction constraint, the placement of downhole tools, or combinations thereof. The drilling path record 314 may be retrieved from a storage location.

In an alternative embodiment, the drilling path record 314 may be generated within the design process 410. The design process 410 can follow method 300 for generating a drilling path record to output the drilling path record. The design process 410 can retrieve the mud-pulse data from a storage computer 114 or from the remote wellsite 116 as shown in FIG. 2. The design process 410 may retrieve the mud system dataset comprising a mud report and periodic datasets of circulation pressure, density, and mud rheology. The design process 410 can process the mud-pulse data and the mud system dataset, as previously described, to generate a processed dataset comprising averaged values and measurement values for the well trajectory (e.g., inclination), wellbore environmental condition values (e.g., temperature and/or pressure, drilling parameter values (e.g., torque, weight on bit, RPM), formation data values (e.g., lithology), and mud data values (such as but not limited to, mud weights, rheology). The design process 410 can separate the processed data values into depth segments 310. The design process 410 can output the drilling path record 314.

At step 419, the design process 410 can input the drilling path record 314 into a drilling fluid model to determine the equivalent circulating density (ECD) of the drilling fluids. The ECD of the drilling fluids, also referred to as the dynamic density, can include a pressure loss due to fluid friction along the wellbore and tubulars and the static density of the drilling fluids. The inputs of the drilling fluid model can include wellbore geometry, e.g., drilling path record 314, mud rheology, mud material properties (included rheology, thermal properties, return rates, and return line temperature), formation properties (including pore pressure, thermal properties, geothermal temperature), specific gravity of solid particles, fluid to solid ratio (including cuttings), drill bit geometry, and ROP. The inputs may be temperature and pressure dependent. The output, e.g., the ECD, includes a hole cleaning efficiency and the wellbore stability based on fluid loss and/or the circulation rate. The design process 410 can utilize the output of the drilling fluid model, e.g., the ECD, as threshold values for the pumping procedure 412 and/or a well cementing hydraulics model as will be described herein.

Continuing the design process 410 on FIG. 4D, in step 422 some embodiments of the design process 410 can input the well geometry and tubulars 416, the inventory of cement and equipment 418, the drilling path record 314, the ECD of the drilling fluid, and a set of client requirements 420 into an isolation barrier analysis process. The term wellbore isolation barrier may refer to Portland cement or a blend of Portland cement that has cured or hardened. The term wellbore isolation barrier can also refer to a polymer that has cured or hardened. In some embodiments, the isolation barrier analysis process can be an isolation barrier analysis model. The isolation barrier analysis process can determine a stress state of the wellbore isolation barrier from the inputs. The isolation barrier analysis process may determine a stress state for each depth segment 310 of the drilling path record 314. The isolation barrier analysis process may determine a lower stress state by applying one or more downhole equipment 414 to a depth segment 310. In some embodiments, the one or more downhole equipment 414 may reduce the stress level of the depth segment 310. The isolation barrier analysis process may generate a first barrier design comprising a wellbore tubular, a wellbore isolation barrier, a downhole equipment 414, or combination thereof with mechanical properties greater than the wellbore stress level. The isolation barrier analysis process can access a historical cementing job database 424 to compare the inputs e.g., the drilling path record 314, to prior cementing jobs. In some embodiments, the isolation barrier analysis process may generate a first barrier design based on one or more characteristics of a prior cementing job. For example, the drilling operation of FIG. 1 may be an offset well from a parent well or within a field of similar wells and the isolation barrier analysis process may retrieve a first barrier design from the records of the parent well from the historical database 424. In an alternate embodiment, the isolation barrier analysis process may generate a first barrier design based on modeling the inputs provided. For example, the isolation barrier analysis process may generate a first barrier design based on modeling the cement placement within the drilling path record 314. The isolation barrier analysis process may be a model, e.g., model 126 of FIG. 2, that the design process, e.g., process 410, inputs data into and receives an output from.

At step 426, a cement blend model may determine a first cement blend based on the first barrier design received from step 422. The cement blend model may be a model, e.g., model 126 of FIG. 2, that the design process, e.g., process 124, inputs data into and receives output from. The design process may input a set of isolation barrier mechanical property requirements for a given set of wellbore environmental conditions, e.g., temperature, pressure, and/or density. The mechanical property requirements may be for at least one depth segment, e.g., depth segment 310E of FIG. 3B. The inputs may also include cement slurry properties including thickening time, fluid loss, gel strength, rheology, density, or combinations thereof. The output from the design process comprises a cement blend. In some embodiments, the output may be a cement blend for at least one depth segment, e.g., depth segment 310E.

At step 428, the first cement blend may be an input into a well cementing hydraulics model. The well cementing hydraulics model can simulate the placement of the cement slurry within the wellbore and generate the pumping procedure, e.g., pumping procedure 412 of FIG. 4B. The placement of the cement slurry can include the equivalent circulating density (ECD), a top of cement (TOC) requirement, a displacement efficiency, or combinations thereof. The inputs for the well cementing hydraulics model may include the drilling path record 314, the well geometry and tubulars 416, a geothermal temperature profile, the pore pressure of the formation 4, the fracture gradient of the formation 4, and properties of various fluids utilized during the cementing operation such as spacers. The drilling fluid model of step 419 can provide threshold values, e.g., pore pressure, based on the ECD of the drilling mud. The properties of the various fluids include rheology and density. The inputs for the well cementing hydraulics model can include downhole equipment 414 such as the number and placement of centralizers and the primary cementing equipment, e.g., float shoe. The well cementing hydraulics model can determine the pumping procedure 412 based on the threshold values. A downhole equipment 414 may be assigned to the at least one depth segment 310 to reduce the operational pumping values, e.g., pressure or flow rate, below a threshold value. The output of the well cementing hydraulics model includes the pumping procedure 412 comprising the volume of the various fluids, pump rates for the various fluids, and eccentricity requirements. The well cementing hydraulics model may be model 126 of FIG. 2.

At step 430, the design process 410 may iterate the design of first cement blend with the cement blend model of step 426 and the well cementing hydraulics model of step 428 with small changes to the first cement blend to converge the results to a threshold value for the model in step 426 and the model in step 428.

At step 432, the simulation and design results are compared to a threshold value from the Lifecycle well analysis of step 422, the cement blend model of step 426, and the well cementing hydraulics model of step 428. The threshold values for the cement blend 408 comprise the mechanical properties (e.g., elastic modulus, strength, friction angle, poisons ratio, shrinkage, thermal properties, thickening time, fluid loss, gel strength, rheology, and/or density), the interface bond strength between the formation 4 and casing, wellbore isolation barrier stress, near wellbore stress, or combinations thereof. The threshold values for the hydraulics model include the pumping procedure 412 schedule, formulation capable of handling loss circulation, thickening time, fluid loss, gel strength, or combinations thereof. Other threshold values may include customer requirements including downhole equipment 414 such as centralizers (number, type and locations), the use of an inner string, multi-stage equipment requirements, or combinations thereof. The threshold values may include requirements for the spacer fluid comprising compatibility with cement and mud, density, rheology, ability to invert the emulsified mud, ability to clean the wellbore, or combinations thereof.

At step 438, if the simulation and design results are below a threshold value, the design process may apply a constraint, e.g., a requirement for a lighter density, and return to step 426 for a revision to the first cement blend, e.g., a second cement blend.

At step 434, if the simulation and design results are below a threshold value and the design process has generate more than one revision to the cement blend, e.g., a fifth, sixth, or seventh cement blend, the design process 410 may generate a failure report. The design process 410 may notify one or more user devices 130 in FIG. 2 of the failure report.

At step 436, the design process 410 may generate a well design recommendation. The design process 410 may include the well design recommendation with the failure report. The well design recommendation may include at least one change to the proposed wellbore construction plans.

At step 440, the design process 410 may compare the first barrier design to the inventory of cement and equipment 418.

At step 442, if at least one material is not available in step 440, the design process 410 may apply a constraint, e.g., exclude or reduce a volume of material, and return to step 426 for a revision to the current revision of the cement blend, e.g., a third cement blend.

At step 444, the design process 410 may generate a laboratory testing request including the current revision of the cement blend and the wellbore design constraints, e.g., wellbore temperature and stress limits.

At step 446, the design process 410 may generate a bill of materials for the downhole equipment 414. Step 446 may be performed concurrent to step 444.

At step 448, the design process 410 may perform laboratory verification on the cement blend including thickening time, fluid loss, mixability, stability of formulation, mechanical properties, and strength. The mechanical properties of the cement blend can include shrinkage, bond strength, gel strength, density, or combinations thereof.

At step 450, the design process 410 may produce laboratory results on samples of the cement blend, spacer fluids, various other chemicals, or combinations thereof.

At step 452, the results of the laboratory verification, e.g., test results, may be added to the laboratory testing database.

At step 454, the design process may generate a cementing proposal. The cementing proposal may comprise the optimized cement design 456 of step 406 of FIGS. 4A and 4B.

The optimized cement design 456 may be tailored to meet various secondary objectives of the design process 410 by applying additional inputs and/or design constraints. The secondary objectives can be specified in the well geometry and tubulars 416, the inventory 418, the client requirements 420, the design constraints of step 438, the design constraints of step 442, or combinations thereof. The secondary objective can be a design objective that includes a reduction in a known wellbore isolation stress state, modifying an existing wellbore isolation barrier, specifying a design requirement for a future operation, specifying a material for the cement blend, excluding a material for the cement blend, or combinations thereof.

The secondary objective can be an operational objective including designing the pumping procedure 412 to utilize existing equipment inventory, to prolong the service life of pumping equipment, to include specific equipment, to exclude specific equipment, or combinations thereof.

The secondary objective can be a cost objective including lowering service cost, reducing the time utilized to design a job, and increasing the operational efficiency. The operational efficiency can be increased by reducing non-productive time (NPT), reducing the time waiting on cement (WOC), or combinations thereof.

The secondary objective can be an inventory objective including increasing inventory turns, utilizing lower cost materials, utilizing widely available materials, avoiding high cost materials, avoiding materials with limited availability, or combinations thereof.

The secondary objective can be an environmental objective that includes a reduction in CO₂ emissions by utilizing non-Portland cement designs and/or by utilizing lower carbon emitting pumping equipment, e.g., natural gas powered and/or electric powered pumping equipment.

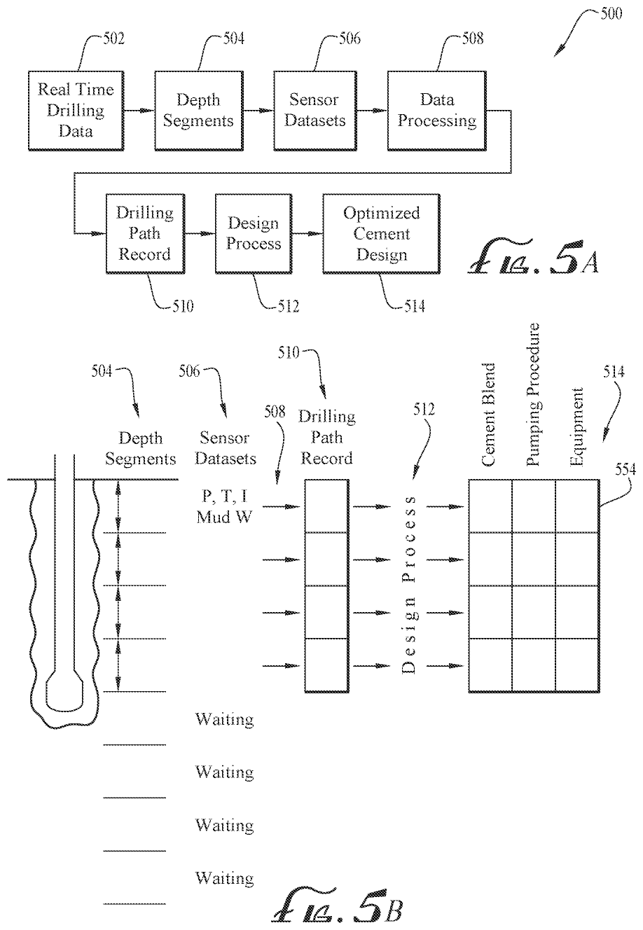

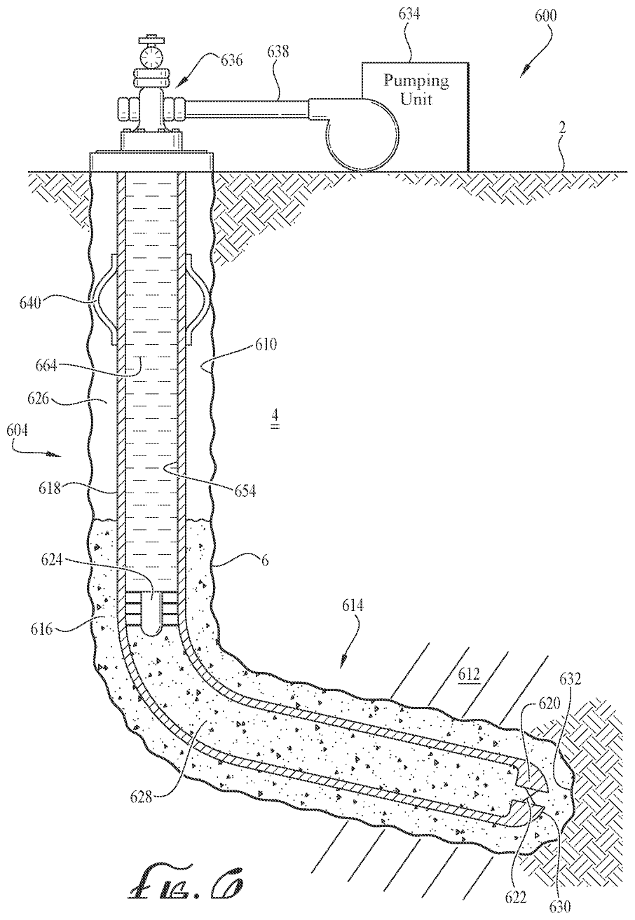

The wellbore drilling operation may be drilling into a formation that is prone to poor wellbore stability and may cause frequent drilling operation irregularities. The formation may cause the drilling operation to be halted before a target depth, e.g., total measured depth, is reached. Changes to the wellbore path, e.g., trajectory, and/or deviations from the design wellbore construction plan may cause the cement design, e.g., the cement blend, to change. An alternate method of designing an optimized cement design is described. Turning now to FIG. 5A, a logical flow diagram depicting a method 500 to generate a cement design record using real-time drilling data is described. In some embodiments, the method 500 of generating a cement design may follow the same design process, e.g., design process 410 of FIG. 4A-4C, utilizing real-time drilling data. At step 502, the method 500 may retrieve real-time drilling data from a remote wellsite 116. The term real-time drilling data is defined as drilling data that are available without delay. It is understood that the process of acquiring the drilling data may include a measurement downhole, a communication of drilling data from a depth in the wellbore to surface, a decoding of signals by a data acquisition device, a transfer of the drilling data from the data acquisition device to a unit controller, e.g. unit controller 42, a transmission of the drilling data via a communication device, e.g., communication device 46, to the design processing portion of method 500. The real-time drilling data is received by the data processing portion without delay.

At step 504, as illustrated in FIG. 5B, the data processing portion can divide the drilling dataset into depth segments 310 as previously described in step 302.

At step 506, as illustrated in FIG. 5B, the data processing portion can divide the measurement data within the drilling dataset into the corresponding depth segments 310A-Z as previously described in step 304.

At step 508, the data processing portion can process the datasets to determine a value representative of the depth segment 310A-Z as previously described in step 306.

At step 510, the data processing portion can generate a drilling path record 314 comprising the average value of the measured data corresponding the depth segments 310A-Z as previously described in step 308.

At step 512, the method 500 may use the drilling path record as an input into a design process, e.g., design process 410, as previously described in FIGS. 4C and 4D. The design process in step 512 be repeated for every depth segment 310 added to the drilling path record 314 as the drilling operation continues to drill deeper, e.g., a greater value of total measured depth. The cement blend may be updated, e.g., revised, as the design process repeats. Alternatively, the design process may be repeated after a number of depth segments are added to the drilling path record 314. For example, the design process may be repeated after every 30 depth segments are added to the drilling path record 314. It is understood that the number of depth segments may be 2, 3, 4, 5, 10, 20, 30, 40, or any number within a range of 1 to 10,000.

At step 514, as illustrated in FIG. 5B, the design process in step 512 can output an optimized cement design 554 comprising a cement blend, a pumping procedure, and a downhole equipment as described in step 406 of FIG. 4B.

In an alternative embodiment, at step 512 the design process may perform a portion of the design process to omit the laboratory testing. The design process of step 512 may input the well geometry and tubulars 416, an inventory of cement and equipment 418, the drilling path record 314, a set of client requirements 420, or combinations thereof into the LifeCycle well analysis of step 422 and continue the design process through steps 426, 428, 430, 432, and 440. The design process may end at step 440 of checking inventory for material availability to omit the laboratory testing of steps 444, 448, 450, and 452. The design process may repeat when the drilling path record 314 is updated with a new depth segment or after the drilling path record 314 is updated with more than one depth segments.

In an alternative embodiment, at step 512 the design process may perform the laboratory testing when notified of the end of the drilling operation. For example, the design process may continually design or revise the cement blend, the cementing procedure, and the downhole equipment as the drilling path record is updated with real-time drilling data. The design process may step to laboratory testing at step 444, step 448, step 450, and step 452 in response to the notification that the drilling operation is complete.

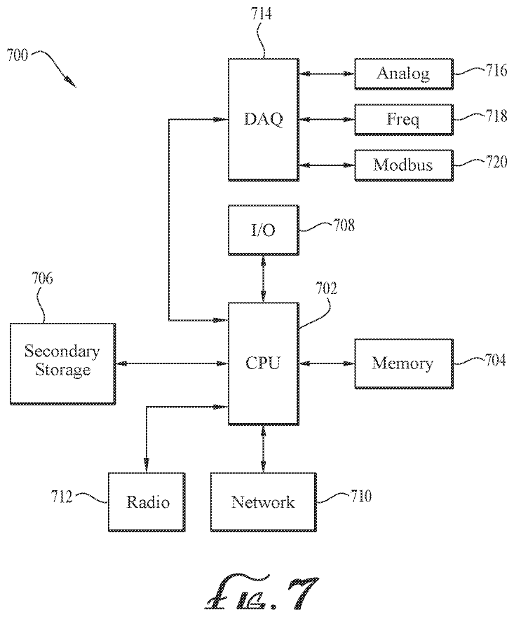

A cementing operation can comprise a cementing unit configured to perform a cementing operation on the wellbore 6 as shown in FIG. 1. Turning now to FIG. 6, illustrated is a cementing operation 600 utilizing an optimized cement design determined by the design process. In some embodiments, the wellsite may be on land and the pumping equipment 634, cement blend 408, and downhole equipment 414 of the optimized cement design 456 may be transported to the wellsite.

In some embodiments, the wellsite on land may provide a larger inventory of materials and equipment for the optimized cement design 456 and thus the cementing operation 600. For example, the downhole equipment 414 specified on the optimized cement design 456 may include centralizers 640, wiper plug 624, and float shoe 620. A greater variety and/or quantity of downhole equipment 414 may be available to a land based cementing operation 600. In another scenario, the cement blend 408 can include various dry additives in a powdered form. The service center can blend, e.g., mix, the cement blend 408 at a service center 120 for transport to the wellsite. The service center 120 may have a greater variety and/or availability of materials for the cement blend 408. In a third scenario, the pumping equipment 634 may be transported from one or more service centers 120 to the wellsite. The service center 120 may have a greater variety and/or availability of pumping equipment 634. In a fourth scenario, one or more pumping equipment 634 may be transported from a second service center to the first service center 120 for use at the wellsite located on land. Utilizing a cement blend 408 comprising dry additives blended at the service center 120 can place a constraint on the design process 410 of the optimized cement design 456 at step 438 and/or step 442.

In contrast, a wellsite located offshore may have a smaller inventory of materials and equipment for the optimized cement design 456. For example, the pumping equipment 634 can be allocated to an offshore platform for multiple wellbore construction projects. The limited availability of space on the offshore platform may prohibit any change or addition of pumping equipment 634. The limitation of utilizing available pumping equipment may place an additional constraint on the design process 410 of the optimized cement design 456 at step 438 and/or step 442 of FIG. 4D. The location offshore can limit the availability of materials for the cement blend 408 and downhole equipment 414. In one scenario, the offshore location may utilize liquid additives instead of dry additives to blend or mix the cement blend 408. The limitation of utilizing available materials and/or downhole equipment 414 may place an additional constraint on the design process 410 of the optimized cement design 456 at step 438 and/or step 442.

A casing string 618 can be conveyed into the wellbore 6 by the drilling rig 20, a workover rig, an offshore rig, or similar structure. A wellhead 636 may be coupled to the casing string 618 at surface 2. The pumping equipment 634, located offshore or on land, can be fluidically coupled to a wellhead 636 by a supply line 638. The wellbore 6 can extend in a substantially vertical direction away from the earth's surface 2 and can be generally cylindrical in shape with an inner bore 610. At some point in the wellbore 6, the vertical portion 604 of the wellbore 6 can transition into a substantially horizontal portion 614. The wellbore 6 can be drilled through the subterranean formation 4 to a hydrocarbon bearing formation 612. Perforations made during the completion process that penetrate the casing 618 and hydrocarbon bearing formation 612 can enable the fluid in the hydrocarbon bearing formation 612 to enter the casing 618.

In some embodiments, the wellbore 6 can be completed with a cementing process that follows a cementing pumping procedure, e.g., pumping procedure 412, to place a cement slurry 628 between the casing string 618 and the wellbore 6. The wellhead 636 can be any type of pressure containment equipment connected to the top of the casing string 618, such as a surface tree, production tree, subsea tree, lubricator connector, blowout preventer, or combination thereof. The wellhead 636 can include one or more valves to direct the fluid flow from the wellbore and one or more sensors that gather pressure, temperature, and/or flowrate data. The pumping equipment 634 can follow a pumping procedure 412 with multiple sequential steps to mix a cement blend 408 with water to form a cement slurry 628 and place the cement slurry 628 into the annular space 626. The pumping procedure 412 can include steps of pumping a spacer fluid to separate the drilling fluid, e.g., drilling mud, from the cement slurry 628. The pumping procedure 412 can include releasing and pumping a cementing wiper plug 624, or similar downhole equipment, to physically separate the drilling fluid from the cement slurry 628. The wiper plug 624 comprises a plurality of flexible fins, or wipers, that sealingly engage the inner surface 654 of the casing 618 with a sliding fit. The pumping equipment 634 can pump a predetermined volume of cement slurry 628 though the supply line 638, through the wellhead 636, and into the casing string 618. A volume of spacer fluid 664 or other type of completion fluid can be pumped after the cementing wiper plug 624 to displace the cementing wiper plug 624 down the casing string 618. The cementing wiper plug 624 can push the cement slurry 628 out the float shoe 620 (or other suitable primary cementing equipment), and into the annular space 626 between the casing string 618 and the wellbore 6. In other embodiments, however, the casing string 618 may be omitted from all or a portion of the wellbore 6 and the principles of the present disclosure can equally apply to an “open-hole” environment. In still other embodiments, however, the primary cementing equipment, e.g., float shoe 620, at the end of the casing string 618 can be drilled out and a liner can be added to extend the length of the wellbore 6.

The cement blend 408 can be Portland cement or a blend of Portland cement with various additives to tailor the cement for the wellbore environment. For example, retarders or accelerators can be added to the cement blend 408 to slow down or speed up the curing process. In some embodiments, the cement blend 408 may vary depending on the depth of the wellbore. In some embodiments, the cement blend 408 can be a polymer designed for high temperatures. In some embodiments, the cement blend 408 can have additives such as expandable elastomer particles.

The cement blend 408 can be mixed with a liquid, e.g., water, to form a cement slurry 628 and placed in the annular space 626 between the casing 18 and the wellbore 6 to cure (harden) and form a wellbore isolation barrier 616, also referred to as a cement sheath.

The unit controller may be a computer system suitable for communication and control of the drilling equipment. In FIG. 1, the unit controller 42 may establish control of the operation of the drilling system, the fluid system, and the communication device 28. In some embodiments, the unit controller 42 may be an exemplary computer system 700 described in FIG. 7. Turning now to FIG. 7, a computer system 700 suitable for implementing one or more embodiments of the unit controller, for example 42, including without limitation any aspect of the computing system associated with the drilling system of FIG. 1 and the remote wellsite 116 of FIG. 2 and the pumping equipment 634 of FIG. 6 and any aspect of a unit control as shown as unit controller 48 in FIG. 1. The computer system 700 may be suitable for implementing one or more embodiments of the computer system in FIG. 2, for example computer system 122, storage computer 114, user devices 130, and customer device 136. The computer system 700 includes one or more processors 702 (which may be referred to as a central processor unit or CPU) that is in communication with memory 704, secondary storage 706, input output devices 708, DAQ card 714, and network devices 710. The computer system 700 may continuously monitor the state of the input devices and change the state of the output devices based on a plurality of programmed instructions. The programming instructions may comprise one or more applications retrieved from memory 704 for executing by the processor 702 in non-transitory memory within memory 704. The input output devices may comprise a Human Machine Interface with a display screen and the ability to receive conventional inputs from the service personnel such as push button, touch screen, keyboard, mouse, or any other such device or element that a service personnel may utilize to input a command to the computer system 700. The secondary storage 706 may comprise a solid state memory, a hard drive, or any other type of memory suitable for data storage. The secondary storage 706 may comprise removable memory storage devices such as solid state memory or removable memory media such as magnetic media and optical media, i.e., CD disks. The computer system 700 can communicate with various networks with the network devices 710 comprising wired networks, e.g., Ethernet or fiber optic communication, and short range wireless networks such as Wi-Fi (i.e., IEEE 802.11), Bluetooth, or other low power wireless signals such as ZigBee, Z-Wave, 6LoWPan, Thread, and WiFi-ah. The computer system 700 may include a long range radio transceiver 712 for communicating with mobile network providers.

The computer system 700 may comprise a DAQ card 714 for communication with one or more sensors. The DAQ card 714 may be a standalone system with a microprocessor, memory, and one or more applications executing in memory. The DAQ card 714, as illustrated, may be a card or a device within the computer system 700. In some embodiments, the DAQ card 714 may be combined with the input output device 708. The DAQ card 714 may receive one or more analog inputs 716, one or more frequency inputs 718, and one or more Modbus inputs 720. For example, the analog input 716 may include a volume sensor, e.g., a tank level sensor. For example, the frequency input 718 may include a flow meter, i.e., a fluid system flowrate sensor. For example, the Modbus input 720 may include a pressure transducer. The DAQ card 714 may convert the signals received via the analog input 716, the frequency input 718, and the Modbus input 720 into the corresponding sensor data. For example, the DAQ card 714 may convert a frequency input 718 from the flowrate sensor into flow rate data measured in gallons per minute (GPM).

The systems and methods disclosed herein may be advantageously employed in the context of wellbore servicing operations, particularly, in relation to the design of a cement blend for a cement operation as disclosed herein.

In some embodiments, a design process may retrieve a drilling dataset indicative of a drilling operation. The design process may generate a drilling path record from the periodic datasets of the drilling dataset. The drilling path record may comprise depth segment with averaged data values. The design process may determine a stress state for the isolation barrier based on the drilling path record and customer inputs. The design process may design a cement blend for each depth segment with mechanical properties that exceed the stress state. A validation process may include laboratory testing. The design process may output an optimized cement design comprising a cement blend for each depth segment, a pumping procedure, and a bill of material for downhole tools for each depth segment.

Additionally or alternatively, the design process can receive real-time drilling datasets indicative of a drilling operation. The design process may update a drilling path record by processing the real-time periodic datasets. The drilling path record may comprise depth segment with averaged data values. The design process may determine a new stress state for the isolation barrier based on the updated drilling path record and customer inputs. The design process may design or revise an existing design of a cement blend for each depth segment with mechanical properties that exceed the new stress state. A validation process may include laboratory testing. The design process may output an optimized cement design comprising a cement blend for each depth segment, a pumping procedure, and a bill of material for downhole tools.

### ADDITIONAL DISCLOSURE

The following are non-limiting, specific embodiments in accordance and with the present disclosure:

A first embodiment, which is a computer-implemented method of designing a wellbore isolation barrier, comprising retrieving, by a design process executing on a processor, at least one dataset associated with drilling a wellbore, wherein the at least one dataset comprises a dataset selected from the group consisting of drilling equipment dataset, bottom hole assembly (BHA) dataset, mud system dataset, or combination thereof, generating, by the processor, a drilling path record comprising at least two depth segments with a plurality of processed data values, wherein the processed data values comprise at least one set of values selected from the group consisting of well trajectory, wellbore environment conditions, drilling parameters, formation data, mud data, or combinations thereof: determining, by the design process, a stress value for the depth segments, designing, by a design process, a cement blend for the depth segments, wherein a mechanical property of the cement blend for the depth segment exceeds a threshold value, and wherein the threshold value is the stress value for the depth segment; and generating, by the design process, the cement blend for each depth segment of the drilling path record.

A second embodiment, which is the method of the first embodiment, further comprising designing, by a design process, a pumping procedure for the depth segments, wherein a set of pump values within the pumping procedure for the cement blend of each depth segment are within a threshold value, and wherein the threshold value is a pore pressure, a leak off rate, or combinations thereof for the depth segment.

A third embodiment, which is the method of any of the first and the second embodiments, further comprising assigning, by a design process, a downhole tool for at least one depth segment, wherein the downhole tool for the depth segment prevents the wellbore isolation barrier or a pumping procedure from exceeding the threshold value for the depth segment.

A fourth embodiment, which is the method of any of the first through the third embodiments, wherein the BHA dataset comprises a mud-pulse dataset, a periodic dataset, or combinations thereof.

A fifth embodiment, which is the method of the fourth embodiment, processing the mud-pulse dataset of the BHA dataset to generate a periodic BHA dataset, a set of measurement values, or combinations thereof.

A sixth embodiment, which is the method of any of the first through the fifth embodiments, further comprising generating a set of depth segments by dividing a measured wellbore into equal parts or unequal parts, determining a segmented set of periodic datasets, a set of measurement values, or combinations thereof for each depth segment, generating a post-processing periodic dataset of each segmented set by applying one or more data reduction techniques to the each segmented set of periodic dataset, wherein the data reduction techniques include data pre-processing, data cleansing, numerosity reduction, or a combination thereof, generating an averaged value for the post-processing periodic dataset by averaging the post-processing periodic dataset with a mathematical averaging technique, wherein the mathematical averaging techniques includes arithmetic mean, a median, a geometric median, a mode, a geometric mean, a harmonic mean, a generalized mean, a moving average, or combination thereof, and assigning a segmented set of processed data values comprising the averaged values, the measurement values, or combinations thereof of to a corresponding depth segment.

A seventh embodiment, which is the method of the sixth embodiment, further comprising storing the drilling path record into a historical database.

A eighth embodiment, which is the method of any of the first through the seventh embodiments, further comprising retrieving, by a stress model, the drilling path record, a design constraint, or combinations thereof, generating a stress state of an isolation barrier, wherein the isolation barrier is a cured cement blend, a tubular, a downhole tool, or combinations thereof, comparing the stress state of the isolation barrier to a threshold value, generating a stress value for each depth segment in response to a threshold value exceeding the stress state, and generating a user notification in response to the stress state exceeding the threshold value.

A ninth embodiment, which is the method of any of the first through the eighth embodiments, further comprising generating a sample of the cement blend for at least one depth segment, testing, by a laboratory test, a plurality of mechanical properties of the cement blend, and validating, by the laboratory test, the cement blend in response to the mechanical properties exceeding the stress value of the at least one depth segment.

A tenth embodiment, which is the method of any of the first through the ninth embodiments, further comprising inputting, by the design process, the stress value for a depth segment, a first cement blend, a design constraint, or combinations thereof, generating, by the design process, a second cement blend in response to the design constraint, the stress value, or a combination thereof, and outputting the second cement blend in response to the mechanical properties of the second cement blend for the depth segment exceeds the stress value.

An eleventh embodiment, which is the method of the tenth embodiment, wherein the design constraint is a material inventory, a wellbore tubular, at least one customer input, or combinations thereof.

A twelfth embodiment, which is the method of the eleventh embodiment, wherein the material inventory comprises an amount of Portland cement.

A thirteenth embodiment, which is the method of any of the first through the twelfth embodiments, further comprising transporting an optimized cement design, a pumping equipment, or combinations thereof to a well site, wherein the optimized cement design comprises a cement blend, a pumping procedure, a downhole tool, or combinations thereof for each depth segment of the drilling path record, mixing a cement slurry, by the pumping equipment, per the pumping procedure, and pumping the cement slurry per the pumping procedure.

A fourteenth embodiment, which is a computer-implemented method of designing a wellbore isolation barrier with real-time drilling data, comprising receiving, by a design process executing on a processor, at least one real-time dataset associated with drilling a wellbore, wherein the at least one real-time dataset comprises a dataset selected from the group consisting of drilling equipment dataset, bottom hole assembly (BHA) dataset, mud system dataset, or combination thereof, updating, by the processor, a drilling path record with real-time datasets, wherein the drilling path record comprises at least two depth segments with processed data values, wherein the processed data values comprises at least one processed set of values selected from the group consisting of well trajectory, wellbore environment conditions, drilling parameters, formation data, mud data, or combinations thereof, determining a stress value for the depth segments, designing, by a design process, a cement blend for each depth segment, wherein a mechanical property of the cement blend for the depth segment exceeds a threshold value, and wherein the threshold value is the stress value for the depth segments, and generating, by the design process, an optimized cement design comprising the cement blend for the depth segments of the drilling path record.

A fifteenth embodiment, which is the method of the fourteenth embodiment, further comprising processing the at least one real-time dataset to generate a current periodic dataset, generating a set of additive depth segments equal in length to a prior depth segments, determining a segmented set of periodic datasets, a set of measurement values, or combinations thereof from the current periodic dataset for each additive depth segment, generating a post-processing periodic dataset of each segmented set by applying one or more data reduction techniques to the each segmented set of the current periodic dataset, wherein the data reduction techniques include data pre-processing, data cleansing, numerosity reduction, or a combination thereof, generating an averaged value for the post-processing periodic dataset by averaging the post-processing periodic dataset with a mathematical averaging technique, wherein the mathematical averaging techniques includes arithmetic mean, a median, a geometric median, a mode, a geometric mean, a harmonic mean, a generalized mean, a moving average, or combination thereof; and updating a drilling path record comprising a segmented set of processed data values comprising averaged values, the measurement values, or combinations thereof of for the corresponding depth segment.

A sixteenth embodiment, which is the method of the fourteenth and the fifteenth embodiments, further comprising retrieving, by a stress model, the drilling path record, a design constraint, or combinations thereof, generating a stress state of an isolation barrier, wherein the isolation barrier is a cured cement blend, a tubular, a downhole tool, or combinations thereof, comparing the stress state of the isolation barrier to a threshold value, generating a stress value for each depth segment in response to a threshold value exceeding the stress state, and generating a user notification in response to the stress state exceeding the threshold value.

A seventeenth embodiment, which is the method of the sixteenth embodiment, wherein the design constraint is a material inventory, a wellbore tubular, at least one customer input, or combinations thereof.

A eighteenth embodiment, which is the method of any of the fourteenth through the seventeenth embodiments, further comprising: inputting, by the design process, the stress value for a depth segment, a first cement blend, a design constraint, or combinations thereof, generating, by the design process, a second cement blend in response to the design constraint, the stress value, or a combination thereof, and outputting the second cement blend in response to the mechanical properties of the second cement blend for the depth segment exceeds the stress value.

A nineteenth embodiment, which is the method of the fourteenth through the eighteenth embodiments, further comprising transporting an optimized cement design to a well site, wherein the optimized cement design comprises a cement blend and a pumping procedure for each depth segment of the drilling path record, mixing a cement slurry, by the pumping equipment, per the pumping procedure, and pumping the cement slurry per the pumping procedure.

An twentieth embodiment, which is a computer-implemented method of designing a wellbore isolation barrier, comprising retrieving, by a design process executing on a processor, a revision one optimized cement design for an isolation barrier at a wellsite from a database, and wherein the revision one optimized cement design comprises a cement blend and a pumping procedure for at least two depth segments of a drilling path record, receiving, by the design process, a real-time dataset indicative of a drilling operation at the wellsite, updating, by the design process, the revision one optimized cement design to a revision two optimized cement design, and communicating the revision two optimized cement design a pumping equipment at the wellsite.

A twenty-first embodiment, which is the method of the twentieth embodiment, further comprising retrieving, by the design process, the drilling path record, a design constraint, or combinations thereof, generating a stress value of the isolation barrier, wherein the isolation barrier is a cured cement blend, a tubular, a downhole tool, or combinations thereof, comparing the stress value of the isolation barrier to a threshold value, generating a stress value for each depth segment in response to the threshold value exceeding the stress value, and generating a user notification in response to the stress value exceeding the threshold value.

A twenty-second embodiment, which is the method of the twentieth and twenty-first embodiment, further comprising retrieving, by the design process, the stress value for a depth segment, a first cement blend, a design constraint, or combinations thereof, generating, by the design process, a second cement blend in response to the design constraint, the stress value, or a combination thereof, and outputting the second cement blend in response to a mechanical property of the second cement blend for the depth segment exceeding the stress value.

A twenty-third embodiment, which is the method of any of the twentieth through the twenty-second embodiments, further comprising stationing the pumping equipment at the wellsite, wherein the pumping equipment is transported to the wellsite or the pumping equipment is assigned to a drilling rig, wherein the pumping equipment includes a unit controller, and wherein the unit controller comprises a processor and memory, transporting a supply of cement materials and downhole equipment to the wellsite, receiving, by the unit controller, a revision two optimized cement design, mixing a cement slurry, by the unit controller, where the cement slurry includes a second cement blend of the revision two optimized cement design, and pumping the cement slurry per the pumping procedure.

A twenty-fourth embodiment, which is a computer-implemented method of designing a wellbore isolation barrier, comprising retrieving, by a design process executing on a processor, at least one dataset associated with drilling a wellbore, wherein the at least one dataset comprises a dataset selected from the group consisting of drilling equipment dataset, bottom hole assembly (BHA) dataset, mud system dataset, or combination thereof, generating, by the processor, a drilling path record comprising depth segments with processed data values, wherein the processed data values comprise at least one of the group consisting of well trajectory, wellbore environment condition values, drilling parameter values, formation data values, mud data values, or combinations thereof, inputting, by the design process, a first set of inputs into a first model, wherein the first model is a drilling fluid model, and wherein the first set of inputs is the drilling path record, the formation data values, the mud data values, or combinations thereof, inputting, by the design process, a second set of inputs into a second model, wherein the second model is an isolation barrier analysis model, wherein the second set of inputs is a first output from the first model, an inventory, a set of client requirements, or combination thereof, inputting, by the design process, a third set of inputs into a third model, wherein the third model is a cement blend model, wherein the third set of inputs is a second output from the second model in response to a mechanical property of a cement blend for the depth segment exceeding a threshold value, a first design constraint, a second design constraint, or combination thereof, inputting, by the design process, a fourth set of inputs into a fourth model, wherein the fourth model is a cementing hydraulics model, wherein the fourth set of inputs is a third output from the third model in response to a set of pumping values within a pumping procedure for the cement blend of the depth segment are within a threshold value, and generating, by the design process, the cement blend for each depth segment of the drilling path record.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A computer-implemented method of designing a wellbore isolation barrier, comprising:
retrieving, by a design process executing on a processor, at least one raw dataset associated with drilling a wellbore, wherein the at least one dataset comprises a dataset selected from the group consisting of drilling equipment dataset, bottom hole assembly (BHA) dataset, mud system dataset, or combination thereof;
generating, by the processor, a drilling path record comprising at least two depth segments with a plurality of processed data values, wherein the processed data values comprise at least one set of values selected from the group consisting of well trajectory, wellbore environment conditions, drilling parameters, formation data, mud data, or combinations thereof;
determining, by the design process, a stress value for the depth segments;
designing, by the design process, a cement blend for the depth segments, wherein a mechanical property of the cement blend for the depth segment exceeds a threshold value, and wherein the threshold value is the stress value for the depth segment; and
generating, by the design process, the cement blend for the depth segments of the drilling path record.

2. The method of claim 1, further comprising:
designing, by the design process, a pumping procedure for the depth segments, wherein a set of pump values within the pumping procedure for the cement blend of each depth segment are within a threshold value, and wherein the threshold value is a pore pressure, a leak off rate, or combinations thereof for the depth segment.

3. The method of claim 1, further comprising:
assigning, by the design process, a downhole tool for at least one depth segment, wherein the downhole tool for the depth segment prevents the wellbore isolation barrier or a pumping procedure from exceeding the threshold value for the depth segment.

4. The method of claim 1, wherein the BHA dataset comprises a mud-pulse dataset, a periodic dataset, or combinations thereof.

5. The method of claim 4, further comprising:
processing the mud-pulse dataset of the BHA dataset to generate a periodic BHA dataset, a set of measurement values, or combinations thereof.

6. The method of claim 1, further comprising:
generating a set of depth segments by dividing a measured wellbore into equal parts or unequal parts;
determining a segmented set of periodic datasets, a set of measurement values, or combinations thereof for each depth segment;
generating a post-processing periodic dataset of each segmented set by applying one or more data reduction techniques to the each segmented set of periodic dataset, wherein the data reduction techniques include data pre-processing, data cleansing, numerosity reduction, or a combination thereof;
generating an averaged value for the post-processing periodic dataset by averaging the post-processing periodic dataset with a mathematical averaging technique, wherein the mathematical averaging techniques includes arithmetic mean, a median, a geometric median, a mode, a geometric mean, a harmonic mean, a generalized mean, a moving average, or combination thereof; and
assigning a segmented set of processed data values comprising the averaged values, the measurement values, or combinations thereof to a corresponding depth segment.

7. The method of claim 6, further comprising:
storing the drilling path record into a historical database.

8. The method of claim 1, further comprising:
retrieving, by a stress model, the drilling path record, a design constraint, or combinations thereof;
generating a stress state of an isolation barrier, wherein the isolation barrier is a cured cement blend, a tubular, a downhole tool, or combinations thereof;
comparing the stress state of the isolation barrier to a threshold value;
generating a stress value for each depth segment in response to a threshold value exceeding the stress state; and
generating a user notification in response to the stress state exceeding the threshold value.

9. The method of claim 1, further comprising:
generating a sample of the cement blend for at least one depth segment;
testing, by a laboratory test, a plurality of mechanical properties of the cement blend; and
validating, by the laboratory test, the cement blend in response to the mechanical properties exceeding the stress value of the at least one depth segment.

10. The method of claim 1, further comprising:
inputting, by the design process, the stress value for a depth segment, a first cement blend, a design constraint, or combinations thereof;
generating, by the design process, a second cement blend in response to the design constraint, the stress value, or a combination thereof; and
outputting the second cement blend in response to a set of mechanical properties of the second cement blend for the depth segment exceeding the stress value.

11. The method of claim 10, wherein the design constraint is a material inventory, a wellbore tubular, at least one customer input, or combinations thereof.

12. The method of claim 11, wherein the material inventory comprises an amount of Portland cement.

13. The method of claim 1, further comprising:
transporting an optimized cement design and a pumping equipment to a well site, wherein the optimized cement design comprises a cement blend, a pumping procedure, a downhole tool, or combinations thereof for the drilling path record;
mixing a cement slurry, by the pumping equipment, per the pumping procedure; and
pumping the cement slurry per the pumping procedure.

14. A computer-implemented method of designing a wellbore isolation barrier with real-time drilling data, comprising:
receiving, by a design process executing on a processor, at least one real-time dataset associated with drilling a wellbore, wherein the at least one real-time dataset comprises a dataset selected from the group consisting of drilling equipment dataset, bottom hole assembly (BHA) dataset, mud system dataset, or combination thereof;
updating, by the processor, a drilling path record with real-time datasets, wherein the drilling path record comprises at least two depth segments with processed data values, wherein the processed data values comprises at least one set of values selected from the group consisting of well trajectory, wellbore environment conditions, drilling parameters, formation data, mud data, or combinations thereof;
determining a stress value for the depth segments;
designing, by the design process, a cement blend for each depth segment, wherein a mechanical property of the cement blend for the depth segment exceeds a threshold value, and wherein the threshold value is the stress value for the depth segments; and
generating, by the design process, an optimized cement design comprising the cement blend for the depth segments of the drilling path record.

15. The method of claim 14, further comprising:
processing the at least one real-time dataset to generate a current periodic dataset;
generating a set of additive depth segments equal in length to a prior depth segments;
determining a segmented set of periodic datasets, a set of measurement values, or combinations thereof from the current periodic dataset for each additive depth segment;
generating a post-processing periodic dataset of each segmented set by applying one or more data reduction techniques to the each segmented set of the current periodic dataset, wherein the data reduction techniques include data pre-processing, data cleansing, numerosity reduction, or a combination thereof;
generating an averaged value for the post-processing periodic dataset by averaging the post-processing periodic dataset with a mathematical averaging technique, wherein the mathematical averaging techniques includes arithmetic mean, a median, a geometric median, a mode, a geometric mean, a harmonic mean, a generalized mean, a moving average, or combination thereof; and
updating a drilling path record comprising a segmented set of processed data values comprising averaged values, the measurement values, or combinations thereof for the corresponding depth segments.

16. The method of claim 14, further comprising:
retrieving, by a stress model, the drilling path record, a design constraint, or combinations thereof;
generating a stress state of an isolation barrier, wherein the isolation barrier is a cured cement blend, a tubular, a downhole tool, or combinations thereof;
comparing the stress state of the isolation barrier to a threshold value;
generating a stress value for each depth segment in response to a threshold value exceeding the stress state; and
generating a user notification in response to the stress state exceeding the threshold value.

17. The method of claim 16, wherein:
the design constraint is a material inventory, a wellbore tubular, at least one customer input, or combinations thereof.

18. The method of claim 14, further comprising:
inputting, by the design process, the stress value for a depth segment, a first cement blend, a design constraint, or combinations thereof;
generating, by the design process, a second cement blend in response to the design constraint, the stress value, or a combination thereof; and
outputting the second cement blend in response to a mechanical property of the second cement blend exceeding the stress value.

19. The method of claim 14, further comprising:
transporting an optimized cement design to a well site, wherein the optimized cement design comprises a cement blend and a pumping procedure for the drilling path record;
mixing a cement slurry, by a pumping equipment, per the pumping procedure; and
pumping the cement slurry per the pumping procedure.

20. A computer-implemented method of designing a wellbore isolation barrier, comprising:
retrieving, by a design process executing on a processor, a revision one optimized cement design for an isolation barrier at a wellsite from a database, and wherein the revision one optimized cement design comprises a cement blend and a pumping procedure for at least two depth segments of a drilling path record;
receiving, by the design process, a real-time dataset indicative of a drilling operation at the wellsite;
updating, by the design process, the revision one optimized cement design to a revision two optimized cement design; and
communicating the revision two optimized cement design to a pumping equipment at the wellsite.

21. The method of claim 20, further comprising:
retrieving, by the design process, the drilling path record, a design constraint, or combinations thereof;
generating a stress value of the isolation barrier, wherein the isolation barrier is a cured cement blend, a tubular, a downhole tool, or combinations thereof;
comparing the stress value of the isolation barrier to a threshold value;
generating a stress value for each depth segment in response to the threshold value exceeding the stress value; and
generating a user notification in response to the stress value exceeding the threshold value.

22. The method of claim 21, further comprising:
retrieving, by the design process, the stress value for a depth segment, a first cement blend, a design constraint, or combinations thereof;
generating, by the design process, a second cement blend in response to the design constraint, the stress value, or a combination thereof; and
outputting the second cement blend in response to a mechanical property of the second cement blend for the depth segment exceeding the stress value.

23. The method of claim 20, further comprising:
stationing the pumping equipment at the wellsite, wherein the pumping equipment is transported to the wellsite or the pumping equipment is assigned to a drilling rig, wherein the pumping equipment includes a unit controller, and wherein the unit controller comprises a processor and memory;
transporting a supply of cement materials and downhole equipment to the wellsite;
receiving, by the unit controller, a revision two optimized cement design;
mixing a cement slurry, by the unit controller, where the cement slurry includes a second cement blend of the revision two optimized cement design; and
pumping the cement slurry per the pumping procedure.
